(19) United States
(12) Patent Application Publication
(10) Pub. No.: US 2010/0003621 A1
(43) Pub. Date: Jan. 7, 2010

(54) Etching method for forming a multi-step surface on a substrate

(75) Inventors: Hui Yin, Dongguan (CN); YongPing Yang, Dongguan (CN)

Correspondence Address: NIXON & VANDERHYE, PC, 901 NORTH GLEBE ROAD, 11TH FLOOR, ARLINGTON, VA, 22203, US

(73) Assignee: SAE Magnetics (H.K.) Ltd.,, Hong Kong (CN)

(21) Appl. No.: 12/216,254

(22) Filed: Jul. 1, 2008

(51) Int. Cl. G03F 7/20

(52) U.S. Cl. 430/323

(57) ABSTRACT

An etching method for forming a multi-step surface on a substrate includes: (1) coating a first photo-resist layer on a predetermined surface of the substrate; (2) coating a second photo-resist layer on the first photo-resist layer, the second photo-resist layer having a characterization opposite to that of the first photo-resist layer; (3) exposing the second photo-resist layer through a first mask so as to form a first removal region; (4) developing the second photo-resist layer to remove the first removal region; (5) exposing the first photo-resist layer through a second mask so as to form a second removal region; (6) developing the first photo-resist layer to remove the second removal region; and (7) etching the predetermined surface of the substrate and the multi-step pattern to form a multi-step surface on the substrate. The present invention also discloses an etching method for forming features on an ABS of a slider.

### FIELD OF THE INVENTION

The present invention relates to an etching method using photo-resist and more particularly to an etching method for forming a multi-step surface on a substrate, and even more particularly to an etching method used to form features on an air bearing surface (ABS) of a slider.

### BACKGROUND OF THE INVENTION

Photolithgraphy, which is a process of transferring the geometric shapes on a mask to a surface of a substrate using a photo-resist, is widely used in the fabricating field of the integrated circuit, conductor and semiconductor devices, sliders of disk drives and so on.

In general, there are two types of photo-resist: positive photo-resist and negative photo-resist. The positive photo-resist is exposed with light wherever the underlying material is to be removed. In the positive photo-resist, exposure to light changes the chemical structure of the photo-resist so that it becomes more soluble in the developing solution. The exposed photo-resist is then washed away by the developing solution in the subsequent developing process, leaving windows of the bare underlying material. The negative photo-resist shows an opposite behavior. The exposure to light causes the photo-resist to become polymerized and more difficult to dissolve. Therefore, the negative photo-resist remains on the surface wherever it is exposed, and the developer solution removes only the unexposed portions.

FIGS. 1a-1b illustrate a conventional process of forming a multi-step surface on a substrate with positive photo-resist and negative photo-resist, respectively. The conventional process of forming a multi-step surface on a substrate generally repeatedly performs a series of process including lithography and etching. Referring to FIG. 1a, taken two step surface as an example, the process includes: coating a layer of positive photo-resist 101a on a predetermined surface of a substrate 100 via a dispenser (not shown); exposing the photo-resist layer 101a through a predetermined mask 102a to light 105; developing the photo-resist 101a to remove the photo-resist in the area exposed to light to form a first photo-resist pattern on the substrate 100; etching the substrate 100 with the first photo-resist pattern as a mask to form a substrate 100a with first depth grooves 104; removing the left photo-resist 101a on the substrate 100a; coating another layer of positive photo-resist 101b on the predetermined surface of the substrate 100a; exposing the photo-resist layer 101b through another predetermined mask 102b to light; developing the photo-resist 101b to form a second photo-resist pattern on the substrate 100a; etching the substrate 100a with the second photo-resist pattern as a mask to form second depth grooves 105 on the substrate 100a, that is to form a substrate 100b; removing all the photo-resist 101b on the substrate 100b. The first depth grooves 104 and the second depth grooves 105 form into a multi-step surface of the substrate 100b.

FIG. 1b shows the above mentioned process with negative photo-resist for forming a multi-step surface on a substrate. The process using negative photo-resists 101a′, 101b′ is similar to that using positive photo-resists 101a, 101b, the difference is that different masks 102a′, 102b′ are used.

As indicated above, a substrate having a multi-step surface is manufactured by repeating the whole process including photolithography and etching multiple times. Thus, the process content and the process lead time are multiple for different depths grooves of the surface. Moreover, the alignment of these two individual lithographic processes becomes critical and results in the complication of the manufacture process flow. Once the misalignment is occurred, the process of rework should be performed, and more seriously, the substrate may be fatally damaged, in turn, the overall cost is increased dramatically.

Hence, a need has arisen for providing an improved method to simplify the process of forming a multi-step surface on a substrate.

### SUMMARY OF THE INVENTION

Accordingly, one objective of the present invention is to provide an etching method for forming a multi-step surface on a substrate, which only uses one time etching, thereby simplifying the manufacturing process and reducing the cost thereof.

Another objective of the present invention is to provide an etching method for forming features on a slider's ABS, which only uses one time etching, thereby simplifying the manufacturing process and reducing the cost thereof.

To achieve the above-mentioned objectives, an etching method for forming a multi-step surface on a substrate comprises the following steps:

(1) coating a first photo-resist layer on a predetermined surface of the substrate;

(2) coating a second photo-resist layer on the first photo-resist layer, the second photo-resist layer having a characterization opposite to that of the first photo-resist layer;

(3) exposing the second photo-resist layer through a first mask so as to form a first removal region in the second photo-resist layer;

(4) developing the second photo-resist layer so as to remove the first removal region;

(5) exposing the first photo-resist layer through a second mask so as to form a second removal region in the first photo-resist layer that is different from the first removal region;

(6) developing the first photo-resist layer so as to remove the second removal region with the reserved regions of the first and the second photo-resist layers forming into a multi-step pattern; and

(7) etching the predetermined surface of the substrate and the multi-step pattern to remove partial substrate material and photo-resist material to form a multi-step surface on the substrate.

In an embodiment of the etching method of the present invention, the etching method further comprises a step of removing all the rest photo-resist material from the substrate.

Preferably, the step (7) comprises: (71) using argon to mill the predetermined surface of the substrate and the multi-step pattern to remove partial substrate material and partial photo-resist material; (72) using oxygen to etch and remove partial photo-resist material; (73) repeating step (71) until the predetermined surface of the substrate is formed into the multi-step surface.

In another embodiment of the etching method of the present invention, the first photo-resist layer is formed by positive photo-resist, and the second photo-resist layer is formed by negative photo-resist.

Preferably, in the step (72) the beam voltage of the oxygen is more than 350V and the beam current flux density of the oxygen is more than 0.004 mA/mm².

In another embodiment of the etching method of the present invention, the step (1) further comprises a step of baking the first photo-resist layer to partially evaporate solvents thereof, the step (2) further comprises a step of baking the second photo-resist layer to partially evaporate solvents thereof, and the step (3) further comprises a step of baking the first and second photo-resist layers after exposing the second photo-resist layer.

An etching method for forming features on an ABS of a slider according to the present invention comprises the steps of:

(1) coating a first photo-resist layer on the ABS of the slider;

(2) coating a second photo-resist layer on the first photo-resist layer, the second photo-resist layer having a characterization opposite to that of the first photo-resist layer;

(3) exposing the second photo-resist layer through a first mask so as to form a first removal region in the second photo-resist layer;

(4) developing the second photo-resist layer so as to remove the first removal region;

(5) exposing the first photo-resist layer through a second mask so as to form a second removal region in the first photo-resist layer that is different from the first removal region;

(6) developing the first photo-resist layer so as to remove the second removal region with the reserved regions of the first and the second photo-resist layers forming into a multi-step pattern; and

(7) etching the ABS of the slider and the multi-step pattern to remove partial material of the slider and photo-resist material to form features on the ABS of the slider.

As an embodiment of the present invention, the method further comprises the steps of: measuring an actual etch depth at selected points on the ABS after removing all photo-resists; and computing a value representative of the uniformity of the actual etch depth.

In comparison with the traditional etching method, which can only form grooves having one depth in one etching process, the etching method of the present invention can form a multi-step surface being formed of grooves with different depths on a substrate in one etching process, the frequency of the substrate uploading to or offloading from a lithography equipment is reduced and the alignment issue and lead time is alleviated. Accordingly, the manufacturing process is simplified, the production cost is reduced, and the throughput is increased.

### BRIEF DESCRIPTION OF THE DRAWINGS

FIG. 1a is a schematic view showing a conventional process of forming a multi-step surface on a substrate using positive photo-resists;

FIG. 1b is a schematic view showing the conventional process of forming a multi-step surface on a substrate using negative photo-resists;

FIG. 2 is a schematic view showing an etching method for forming a multi-step surface on a substrate according to one embodiment of the present invention;

FIG. 3 is a schematic view showing an etching process of the etching method shown in FIG. 2;

FIG. 4 is a flow chart of an etching method for forming features on an ABS of a slider according to another embodiment of the present invention;

FIG. 5a shows an ABS of a slider formed by the conventional process shown in FIGS. 1a-1b; and

FIG. 5b shows an ABS of a slider formed by the etching method of the present invention.

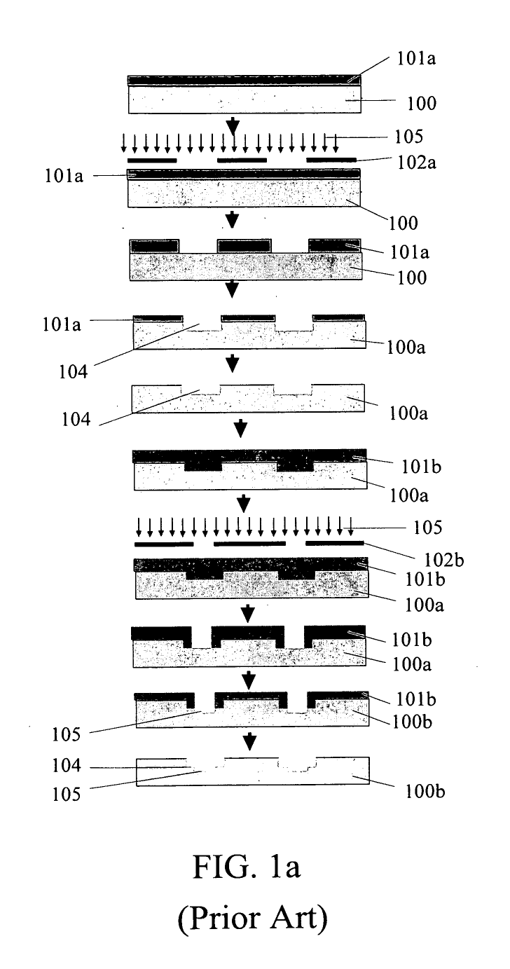

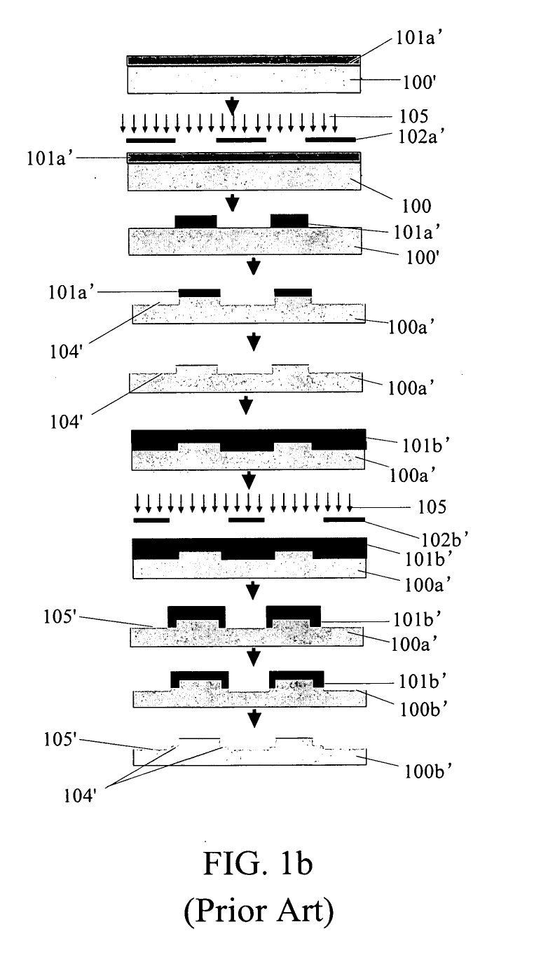

### DETAILED DESCRIPTION OF ILLUSTRATED EMBODIMENTS

Various preferred embodiments of the invention will now be described with reference to the figures, wherein like reference numerals designate similar parts throughout the various views. As indicated above, the invention is directed to an etching method for forming a multi-step surface on a substrate, which is capable of simplifying the manufacturing process and reducing the cost.

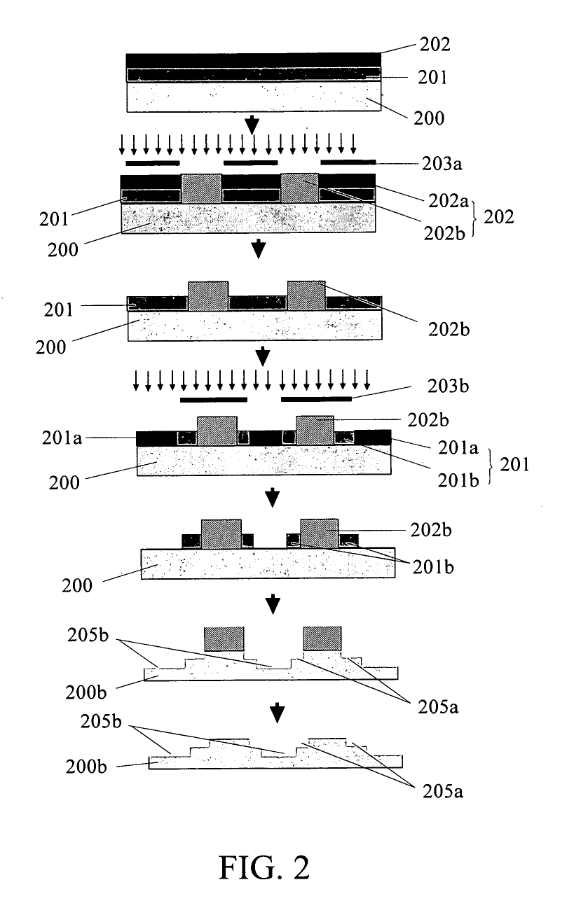

Referring to FIG. 2, the deeper layer represents a negative photo-resist, while the shallower one represents a positive photo-resist. Taken two layers of photo-resists as an example, a preferred embodiment of the etching method according to the present invention is described in detail as followed.

Firstly, provide a substrate 200, which can be a wafer to be etched, a semiconductor substrate, or an incomplete semiconductor device. Then coat a first photo-resist layer 201 formed by positive photo-resist on a predetermined surface of the substrate 200 and bake the first photo-resist layer 201 to partially evaporate the solvents thereof. Next, coat a second photo-resist layer 202 formed by negative photo-resist on the first photo-resist layer 201 and bake the second photo-resist layer 202 to partially evaporate the solvents thereof.

Secondly, expose the second photo-resist layer 202 through a first mask 203a so as to form a first removal region 202a in the second photo-resist layer 202. Then, develop the second photo-resist layer 202 to remove the photo-resists in the first removal region 202a.

Thirdly, expose the first photo-resist layer 201 through a second mask 203b so as to form a second removal region 201a that is different from the first removal region 202a in the first photo-resist layer 201. Then, develop the first photo-resist layer 201 to remove the photo-resists in the second removal region 201a. The reserved regions 202b, 201b of the first and the second photo-resist layers 202, 201 form into a multi-step pattern on the substrate 200.

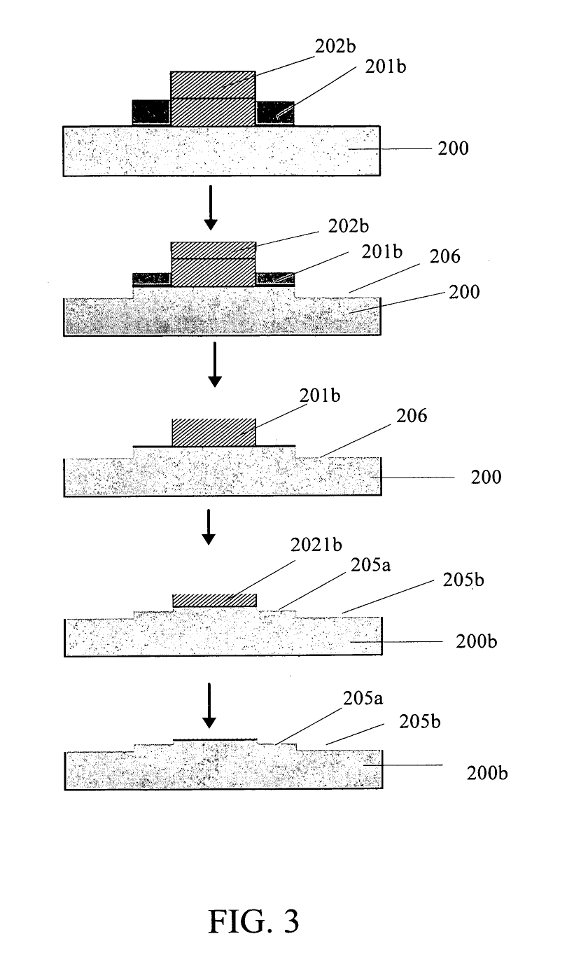

Fourthly, as shown in FIG. 3, the etching process is illustrated as followed. The etching process includes: (a) using argon to mill the predetermined surface of the substrate 200 and the multi-step pattern to remove partial substrate material to form grooves 206 and partial photo-resist material in the areas 202b, 201b; (b) using oxygen to etch and remove partial photo-resist material in the areas 202b, 201b; (c) using argon to mill the predetermined surface of the substrate 200 and the multi-step pattern to remove partial substrate material to form a substrate 200b having grooves 205a and 205b with different depths and partial photo-resist material in the area 201b.

Preferably, the beam voltage of the oxygen is more than 350V and the beam current flux density of the oxygen is more than 0.004 mA/mm².

Finally, remove all the photo-resist materials on the substrate 200b.

It should be noted that this invention is not limited to two photo-resist layers described above. More than two photo-resist layers can be used to form a multi-step surface composed by grooves having more than two depths as long as two adjoining layers thereof have opposite characterization.

Since the etching method of the present invention forms a multi-step photo-resist pattern on the substrate and then etches the substrate to form a multi-step surface at one time, so the frequency of a substrate uploading to or offloading from a lithography equipment is reduced and the alignment issue is alleviated, in turn, the lead time and is reduced and the process is simplified, therefore, the production cost is reduced, and the throughput is increased.

It is noted that though the present invention is illustrated in cross-sectional views, the patterns of the masks can vary with the design need of different devices and are not limited to the embodiments.

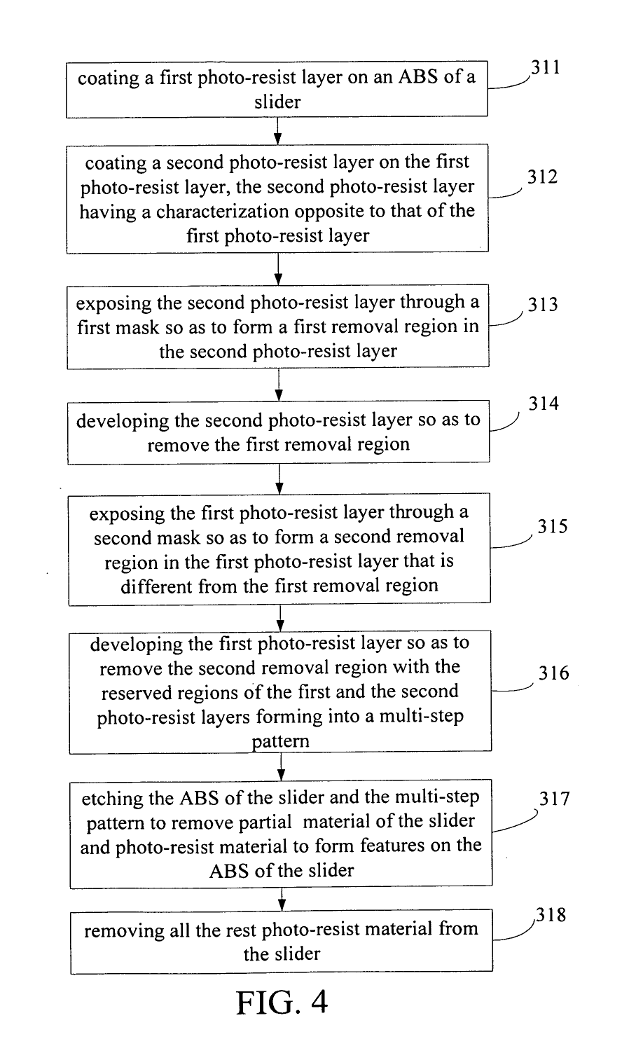

In another embodiment of the present invention, the above-mentioned etching method is used in the process of manufacturing sliders. Typically, a slider is formed with an aerodynamic pattern of protrusions (air-bearing features) on the air bearing surface (ABS) which enable the slider to fly at a constant height close to the disk during operation of the disk drive. More complicated the features on the ABS of the slider are, more layers of photo-resists are needed. FIG. 4 is a flow chart illustrating the process of forming features on a slider's ABS using the etching method of the present invention. As shown in FIG. 4, the etching method for forming features on a slider's ABS includes:

(311) coating a first photo-resist layer on the ABS of the slider;

(312) coating a second photo-resist layer on the first photo-resist layer, the second photo-resist layer having a characterization opposite to that of the first photo-resist layer;

(313) exposing the second photo-resist layer through a first mask so as to form a first removal region in the second photo-resist layer;

(314) developing the second photo-resist layer so as to remove the first removal region;

(315) exposing the first photo-resist layer through a second mask so as to form a second removal region in the first photo-resist layer that is different from the first removal region;

(316) developing the first photo-resist layer so as to remove the second removal region with the reserved regions of the first and the second photo-resist layers forming into a multi-step pattern;

(317) etching the ABS of the substrate and the multi-step pattern to remove partial substrate material and photo-resist material to form features on the bearing surface of the slider; and

(318) removing all the rest photo-resist material from the slider.

After removing all photo-resist material from the slider, the etch depths at different points of the slider are measured to make sure of the etching uniformity.

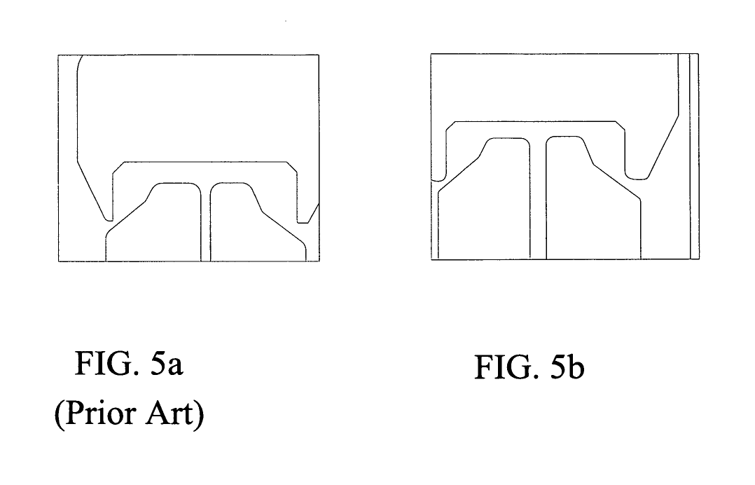

FIGS. 5a-5b show the features formed on partial ABS of the slider with the conventional method and the etching method shown in FIG. 4, respectively. It can be seen that air bearing features on the ABS of the slider is clear, that is to say, the etching method of the present invention is doable.

It should be noted that the sliders are processed at the row level as a manufacturing convenience and that the sliders may also be cut from the row before processing.

The foregoing description of the present invention has been presented for purposes of illustration and description. It is not intended to be exhaustive or limit the invention to the precise form disclosed, and obviously many modifications and variations are possible in light of the above teaching. Such modifications and variations that may be apparent to those skilled in the art are intended to be included within the scope of this invention as defined by the accompanying claims.

What is claimed is:

1. An etching method for forming a multi-step surface on a substrate, comprising the steps of:
(1) coating a first photo-resist layer on a predetermined surface of the substrate;
(2) coating a second photo-resist layer on the first photo-resist layer, the second photo-resist layer having a characterization opposite to that of the first photo-resist layer;
(3) exposing the second photo-resist layer through a first mask so as to form a first removal region in the second photo-resist layer;
(4) developing the second photo-resist layer so as to remove the first removal region;
(5) exposing the first photo-resist layer through a second mask so as to form a second removal region in the first photo-resist layer that is different from the first removal region;
(6) developing the first photo-resist layer so as to remove the second removal region with the reserved regions of the first and the second photo-resist layers forming into a multi-step pattern; and
(7) etching the predetermined surface of the substrate and the multi-step pattern to remove partial substrate material and photo-resist material to form a multi-step surface on the substrate.

2. The etching method as claimed in claim 1, further comprising a step of removing all the rest photo-resist material from the substrate.

3. The etching method as claimed in claim 1, wherein the first photo-resist layer is formed by positive photo-resist, and the second photo-resist layer is formed by negative photo-resist.

4. The etching method as claimed in claim 1, wherein the step (7) comprises: (71) using argon to mill the predetermined surface of the substrate and the multi-step pattern to remove partial substrate material and partial photo-resist material; (72) using oxygen to etch and remove partial photo-resist material; (73) repeating step (71) until the predetermined surface of the substrate is formed into the multi-step surface.

5. The etching method as claimed in claim 4, wherein the beam voltage of the oxygen is more than 350V and the beam current flux density of the oxygen is more than 0.004 mA/mm².

6. The etching method as claimed in claim 1, wherein the step (1) further comprises a step of baking the first photo-resist layer to partially evaporate solvents thereof, the step (2) further comprises a step of baking the second photo-resist layer to partially evaporate solvents thereof, and the step (3) further comprises a step of baking the first and second photo-resist layers after exposing the second photo-resist layer.

7. An etching method for forming features on an air bearing surface of a slider comprising the steps of:
(1) coating a first photo-resist layer on the air bearing surface of the slider;
(2) coating a second photo-resist layer on the first photo-resist layer, the second photo-resist layer having a characterization opposite to that of the first photo-resist layer;
(3) exposing the second photo-resist layer through a first mask so as to form a first removal region in the second photo-resist layer;
(4) developing the second photo-resist layer so as to remove the first removal region;
(5) exposing the first photo-resist layer through a second mask so as to form a second removal region in the first photo-resist layer that is different from the first removal region;
(6) developing the first photo-resist layer so as to remove the second removal region with the reserved regions of the first and the second photo-resist layers forming into a multi-step pattern; and
(7) etching the air bearing surface of the slider and the multi-step pattern to remove partial material of the slider and photo-resist material to form features on the bearing surface of the slider.

8. The etching method as claimed in claim 7, further comprising a step of removing all the rest photo-resist material from the slider.

9. The etching method as claimed in claim 7, wherein the first photo-resist layer is formed by positive photo-resist, the second photo-resist layer is formed by negative photo-resist.

10. The etching method as claimed in claim 7, further comprising the steps of: measuring an actual etch depth at selected points on the air bearing surface after removing all photo-resists; and computing a value representative of the uniformity of the actual etch depth.

11. The etching method as claimed in claim 7, wherein the step (7) comprises: (71) using argon to mill the air bearing surface of the slider and the multi-step pattern to remove partial slider material and partial photo-resist material; (72) using oxygen to etch and remove partial photo-resist material; (73) repeating step (71) until the features are formed on the air bearing surface of the slider.

12. The etching method as claimed in claim 11, wherein the beam voltage of the oxygen is more than 350V and the beam current flux density of the oxygen is more than 0.004 mA/mm².

13. The etching method as claimed in claim 7, wherein the step (1) further comprises a step of baking the first photo-resist layer to partially evaporate solvents thereof, the step (2) further comprises a step of baking the second photo-resist layer to partially evaporate solvents thereof, and the step (3) further comprises a step of baking the first and second photo-resist layers after exposing the second photo-resist layer.
